(19) United States
(12) Patent Application Publication
(10) Pub. No.: US 2007/0235322 A1
(43) Pub. Date: Oct. 11, 2007

(54) Method for real-time monitoring the fabrication of magnetic memory units

(75) Inventors: Jong-Ching Wu, Changhua City (TW); Lien-Hui Horng, Changhua City (TW); Yi-Hom Hsu, Changhua City (TW); Che-Chin Chen, Changhua City (TW)

Correspondence Address: BIRCH STEWART KOLASCH & BIRCH, PO BOX 747, FALLS CHURCH, VA, 22040-0747, US

(73) Assignee: NATIONAL CHANGHUA UNIVERSITY OF EDUCATION

(21) Appl. No.: 11/397,638

(22) Filed: Apr. 5, 2006

(51) Int. Cl. C23C 14/00

(52) U.S. Cl. 204/192.34

(57) ABSTRACT

A method for real-time monitoring the fabrication of magnetic memory units uses an ion beam milling machine, mainly using plasma to etch the films. The method for real-time measuring resistance during etching can acquire the charge carriers' transport characteristics of tunneling resistance with current perpendicular to the plane of film. By means of monitoring the etching end point by a module of tunneling magneto-resistance (TMR) memory unit on the chip, other tunneling magneto-resistance memory units on the chip can be fabricated in situ. By controlling applied voltage and etch time of the etch machine, samples of varying film thicknesses can be obtained. Different materials have different etch rates which depends on the amount of argon, applied voltage and accelerated voltage used in etching. This invention can modulate adequate parameters according to the requirements of different products, whose advantages include real-time management and analysis of non-conformities and causes.

### BACKGROUND

1. Field of Invention

The present invention relates to a method of real-time monitoring fabrication of magnetic memory units, and more particularly to a method for controlling dry etching process using real-time resistance measurement.

2. Description of Related Art

Magnetic Random Access Memory (MRAM) is a kind of non-volatile random access memory which stores data by its magnetic properties instead of by electronic properties as with traditional memories like Flash memory, Static Random Access Memory (SRAM) and Dynamic Random Access Memory (DRAM). MRAM has abandoned the traditional electronic transmission method. The advantages of MRAM are that its read and write time is as quick as SRAM while its memory capacity is as large as DRAM. MRAM has a read time 2400 times faster than DRAM and has acceptable yield of production without needing to increase its chip area. Furthermore, MRAM power consumption is much lower than SRAM and is equal to or lower than Flash memory and DRAM.

Some experts forecast that when MRAM has been researched and developed thoroughly, the semiconductor industry will be shaken up, leading to new semiconductor products worldwide and the extinction of products like Flash memory, SRAM and DRAM.

Two general kinds of MRAM memory units exist at present. One is giant magnetoresistance (GMR) device; another is tunneling magnetoresistance (TMR) device. The magnetic tunnel junction (MTJ) is a general structure of the TMR memory unit. In the multi-layer structure of the TMR memory unit, there must be a very thin and dense insulation layer made of Al₂O₃ or MgO mostly. The operating principle of a TMR-based MRAM cell relies on the electron spin characteristics and tunneling effect to reach the necessary variation of resistance for recording the “0” and “1” signals.

Reference is made to FIG. 1, which illustrates a known TMR memory unit 1, comprising a substrate 11, biasing layer 12, a pinned layer 13, a very thin and dense insulation layer 14 and a free layer 15.

Reference is also made to FIG. 2, which illustrates a magnetic tunnel junction 2 and measuring current perpendicular to the plane. The MTJ comprises a substrate 21, a pinned layer 22, an insulation layer 23 and a free layer 24, wherein the free layer 24 receives an incoming current 25; and the pinned layer 22 sends an outgoing current 26 for measuring the magnetoresistance of the magnetic tunnel junction 2.

Generally, making an MRAM component comprises defining a pattern on a coated multi-layer film, then etching the multi-layer film to create many magnetic tunnel junctions (MTJ).

There are two major types of etching: wet etching and dry etching. Ion beam milling is a kind of dry etching process, which uses a beam of ionized Argon (Ar) to dislodge the material from the sample surface. The feature of this etching process is that the sample is non-selectively bombarded by the ion beam. During the etching process, most of etched materials are removed out of the chamber by an air extracting apparatus after ion etching process. Some etching residue nonetheless redeposit on the sample.

Reference is made to FIG. 3, which illustrates a magnetic tunnel junction 3 comprising a pinned layer 32, a barrier layer 33, a free layer 34 and a photoresist 35. An ion beam milling process 36 is applied on the magnetic tunnel junction 3. The structure of the magnetic tunnel junction needs a very thin barrier layer 33; its thickness is about 1 nanometer (nm), and the material is Al₂O₃ or MgO mostly.

Reference is made to FIG. 4, illustrating a shorting problem of a magnetic tunnel junction 3. The etched residues 37 are resputtered on the sidewall of barrier layer 33. Consequently, when current passes through the short 37, the magnetic tunnel junction 3 loses its tunneling magnetic resistance effect. Furthermore, the magnetic tunnel junction 3 is unable to determine the “1” or “0” signals.

The above-mentioned problems encountered by magnetic devices consisting of multilayer films of various materials are solved by the present invention.

### SUMMARY

In order to solve the above-mentioned and other problems and to achieve the technical advantages of the present invention, the present invention provides a method for manipulating dry etching process by instantaneously measuring resistance of device during etching. It is therefore an objective of the present invention to provide a method for real-time monitoring the fabrication of magnetic memory units. The method uses plasma to etch the film, wherein the film is a single-layer film or multi-layer film, and the material of the film is metallic or magnetic material. During the etching process, the change of real-time resistance indicates the carrier-transmitting characteristics of the magnetic tunnel junction. The etching depth can be controlled by changing etching conditions such as voltage or etching time. The etching rate of different materials is not the same. It depends on the amount of Argon gas, operating voltage and accelerating voltage. There are several advantages listed below:

1. Real-time monitoring and controlling the coating process enables:
(a) real-time monitoring the coating quality;
(b) prevent imperfect coating, thus avoiding the waste in the follow-up processes;
(c) raising the yield of production and lowering the total cost.

2. Real-time monitoring unusual discharge and analyzing its reason according to the monitored record enables:
(a) Finding the reasons of imperfect products quickly;
(b) searching for discrepant entries in the monitored record; and
(c) raising the efficiency of failure mode and effects analysis.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings,

FIG. 1 illustrates a prior art showing the multi-layer structure of a magnetic tunnel junction memory unit;

FIG. 2 illustrates a prior art showing a method to measure current perpendicular to the plane of the preferred embodiment of the present invention;

FIG. 3 illustrates a prior art showing the memory unit before the ion beam milling process of the preferred embodiment of the present invention;

FIG. 4 illustrates a prior art showing the memory unit after the ion beam milling process of the preferred embodiment of the present invention;

FIG. 5 illustrates a single-layer NiFe film on a substrate of the preferred embodiment of the present invention;

FIG. 6 illustrates gold pads on the single-layer NiFe film of the preferred embodiment of the present invention;

FIG. 7 is a cross-sectional view schematically showing an example of an ion beam milling process and a real-time resistance measurement applied on the single-layer structure of the preferred embodiment of the present invention;

FIG. 8 is a cross-sectional view schematically showing an example of an ion beam milling process and a real-time resistance measurement continuously applied on the single-layer structure of the preferred embodiment of the present invention;

FIG. 9 is a cross-sectional view schematically showing an example of a real-time resistance measurement after ion beam milling process applied on the single-layer structure of the preferred embodiment of the present invention;

FIG. 10 is the test results of the NiFe film's resistance versus etching time and the inset is the film thickness versus etching time;

FIG. 11 is a cross-sectional view schematically showing an example of a multi-layer structure of the preferred embodiment of the present invention;

FIG. 12 is a cross-sectional view schematically showing an example of gold pads deposited on the multi-layer structure of the preferred embodiment of the present invention;

FIG. 13 is a cross-sectional view schematically showing an example of a real-time resistance measurement before ion beam milling applied on a multi-layer structure of the preferred embodiment of the present invention;

FIG. 14 is a cross-sectional view schematically showing an example of an ion beam milling and a real-time resistance measurement applied on multi-layer structure of the preferred embodiment of the present invention; and

FIG. 15 is a cross-sectional view schematically showing an example of a resistance measurement after ion beam milling applied on multi-layer structure of the preferred embodiment of the present invention.

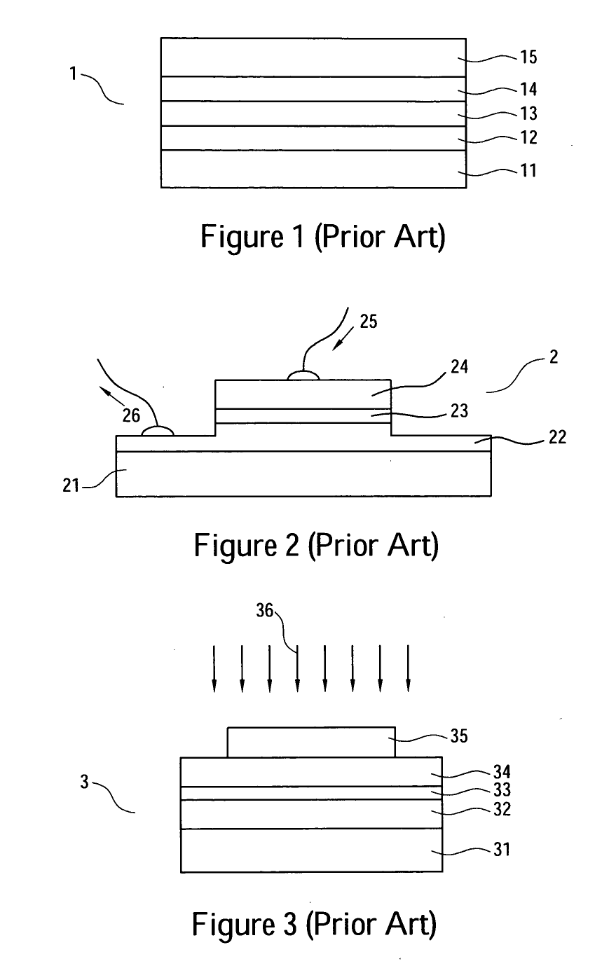

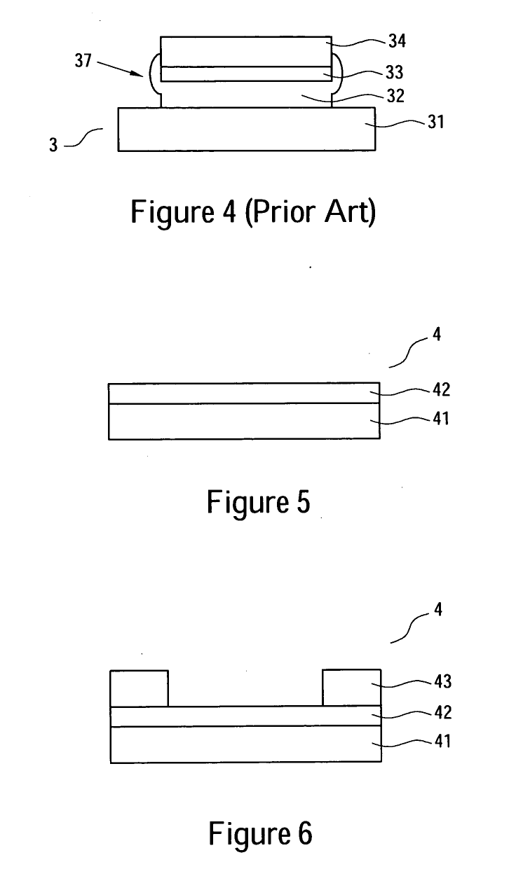

### DESCRIPTION OF THE PREFERRED EMBODIMENTS

Reference is now made in detail to the present preferred embodiments of the invention, examples of which are illustrated in the accompanying drawings. Wherever possible, the same reference numbers are used in the drawings and the description to refer to the same or like parts.

While the specification concludes with claims defining the features of the invention that are regarded as novel, it is believed that the invention is better understood from a consideration of the following description in conjunction with the figures, in which like reference numerals are carried forward.

A method for real-time monitoring the fabrication of magnetic memory units 4 can control the etching thickness precisely by real-time measuring resistance of the films therein. The method of the preferred embodiment of the present invention is as follows:

(a) Grow a single layer 42 on a substrate 41. (Reference is made to FIG. 5.)

(b) Apply a metal electrode on the topmost layer of the film. The material of the metal electrode can be gold (Au). (Reference is made to FIG. 6.)

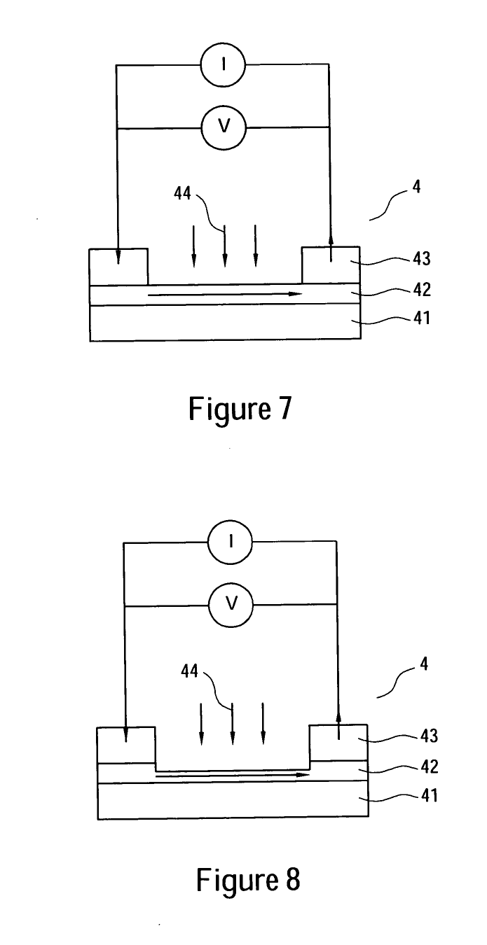

(c) Apply an ion beam milling process 44 while measuring the resistance of the magnetic memory units 4. (Reference is made to FIG. 7, of which the arrows represent direction of current.)

(d) While applying the ion beam milling process 44 such that the single layer 42 is etched gradually, measure the resistance of the magnetic memory units 4 continuously until the resistance slightly rises, implying that the single layer 42 has become thinner. (Reference is made to FIG. 8.)

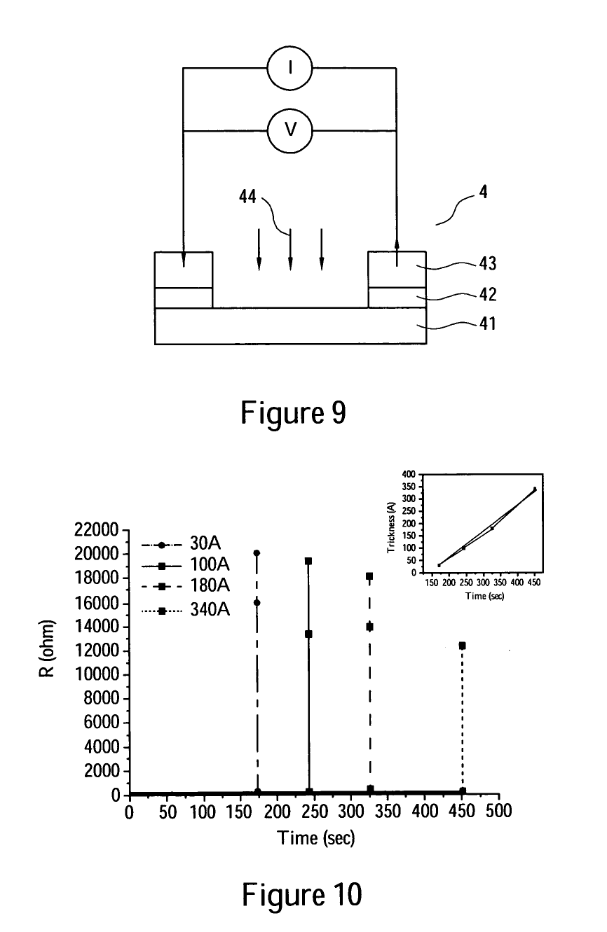

(e) Continue applying the ion beam milling process 44 until etching to the substrate 41, thus making the magnetic memory units 4 become broken circuits. (Reference is made to FIG. 9.)

Reference is made to FIG. 10, plotting test results of the resistance of the single layer (NiFe film) 42 versus etching time. Where the resistance diverges on the graph represent when the single layer 42 was totally etched. The inset shows the linear relationship of film thickness versus etching time. This means that the film thickness is direct proportion to the etching time.

A known method for measuring resistance by passing current perpendicular to plane (CPP) to a magnetic tunnel junction needs several additional processes. The steps of the preferred embodiment of the present invention are as follows:

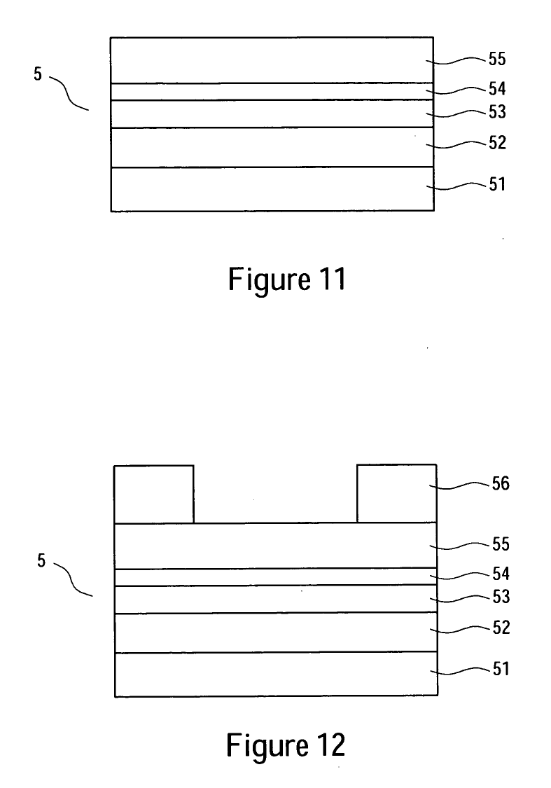

(a) Provide a tunneling magneto resistance memory unit 5 comprising a substrate 51, a bias layer 52, a pinned layer 53, a barrier layer 54 and a free layer 55. (Reference is made to FIG. 11.)

(b) Deposit a metal electrode on the topmost layer of the film. The metal can be gold (Au). (Reference is made to FIG. 12.)

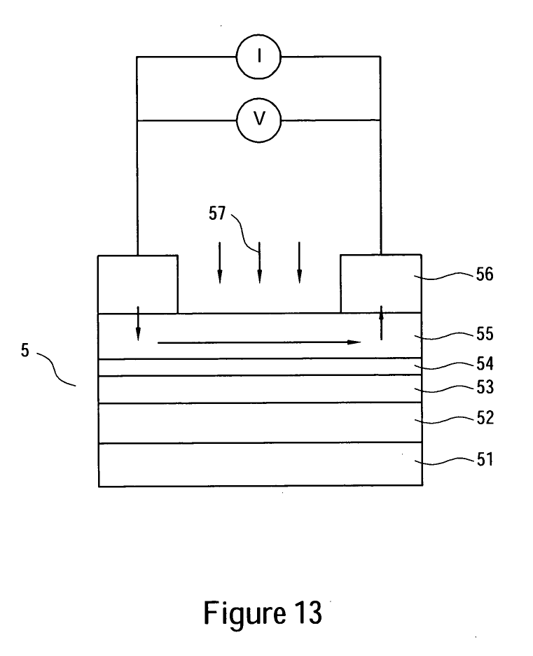

(c) Apply an ion beam milling process 57 on tunneling magnetoresistance memory unit 5 while measuring the real-time resistance. At beginning of etching process, the current passes through the free layer 55, leading to a low resistance. (Reference is made to FIG. 13.)

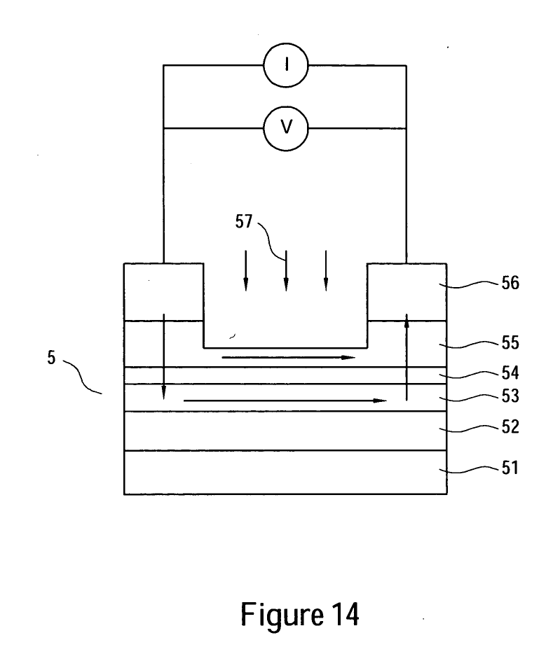

(d) Continue applying the ion beam milling process 57. The free layer 55 is etched gradually. The real-time resistance is therefore slightly increased. There would be two kinds of current transmitting paths. (Reference is made to FIG. 14.)

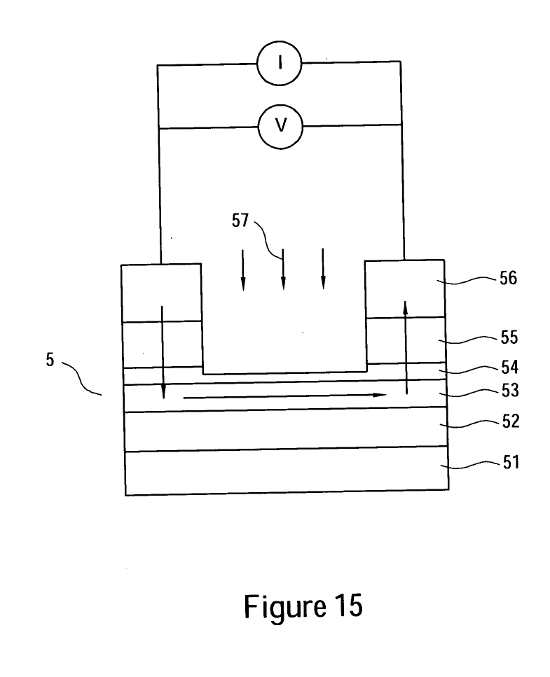

(e) Continue applying the ion beam milling process 57 until the free layer 55 is entirely etched, thus confining the current to pass through the barrier layer 54 and allowing one to measure the magnetoresistance of two tunneling junctions in series connection. For the purpose of avoiding a shorting problem of tunneling magnetoresistance memory unit 5, the critical etching time when the free layer 55 is entirely etched can be precisely controlled. (Reference is made to FIG. 15.)

All semiconductor manufacturing processes of the preferred embodiment of the present invention use current lithography technology to define every magnetic tunnel junction unit. Using current etching technology and real-time resistance measurement to observe the variation of resistance when etching multi-layer films, the end point of etching can be controlled by the change of resistance.

The ion beam milling process can produce over 10 million magnetic tunnel junction memory units on a 2-inch (or 4-inch) diameter silicon wafer. Only two magnetic tunnel junctions are necessary for real-time monitoring to control the etching end point. Thus, all other magnetic tunnel junctions can be defined and are saleable.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for real-time monitoring the fabrication of magnetic memory units, comprising:
(a) growing a film on a substrate;
(b) applying a metal electrode on the topmost layer of the film;
(c) applying an ion beam milling process to the film;
(d) applying the ion beam milling process to the film while carrying out a resistance measurement;
(e) applying the ion beam milling process to the film continuously such that the film is etched gradually to become thinner; and
(f) applying the ion beam milling process to the film until etching to the substrate, such that each magnetic memory unit becomes a broken circuit, wherein when the magnetic memory units become broken circuits, the method for real-time measuring the resistance and real-time monitoring the fabrication of the magnetic memory units is completed.

2. The method of claim 1, wherein the film is a metal film.

3. The method of claim 1, wherein the film is a single-layer metallic film.

4. The method of claim 1, wherein the film is a multi-layer film.

5. The method of claim 1, wherein the film is a nickel-iron (NiFe) film.

6. The method of claim 1, wherein the film is a single-layer nickel-iron NiFe) film.

7. The method of claim 1, wherein the film is a multi-layer nickel-iron (NiFe) film.

8. The method of claim 1, wherein the film is a magnetic film.

9. The method of claim 1, wherein the film is a single-layer magnetic film.

10. The method of claim 1, wherein the film is a multi-layer magnetic film.

11. The method of claim 1, wherein the way of applying a metal electrode is a semiconductor manufacturing process.

12. A method for real-time monitoring the fabrication of a tunneling magnetic resistance memory unit, comprising:
(a) covering a multi-layer structure of the tunneling magnetic resistance memory unit progressively on a substrate;
(b) applying at least one gold electrode on the topmost layer of the tunneling magnetic resistance memory unit;
(c) applying an ion beam milling process to the tunneling magnetic resistance memory unit;
(d) applying an ion beam milling process to the film while carrying out a resistance measurement;
(e) applying the ion beam milling process continuously such that the highest layer of the tunneling magnetic resistance memory unit is etched gradually, while measuring the variation of the resistance value continuously;
(f) applying the ion beam milling process continuously until etching to the last layer of the tunneling magnetic resistance memory unit, coinciding with when the resistance value of real-time measuring increases; and
(g) controlling the time point of the etching to the last layer of the tunneling magnetic resistance memory unit by aforementioned phenomenon in step (f), wherein a magnetic tunnel junction unit can be defined, and the method for etching and real-time measuring the resistance of real-time monitoring the fabrication of the magnetic memory units is completed.

13. The method of claim 12, wherein the multi-layer structure comprises at least one bias layer, at least one pinned layer, at least one barrier layer and at least one free layer.

14. The method of claim 12, wherein the topmost layer is the free layer.

15. The method of claim 12, wherein the way of applying at least one gold electrode is a semiconductor manufacturing process.

16. The method of claim 12, wherein the bottommost layer is the bias layer.
